(19) United States
(12) Patent Application Publication
(10) Pub. No.: US 2018/0335231 A1
(43) Pub. Date: Nov. 22, 2018

(54) DUAL HEAT PIPE THERMOELECTRIC COOLER

(71) Applicant: Adelbert M. Gillen, Deerfield Beach, FL (US)

(72) Inventor: Adelbert M. Gillen, Deerfield Beach, FL (US)

(21) Appl. No.: 16/048,852

(22) Filed: Jul. 30, 2018

Related U.S. Application Data
(63) Continuation-in-part of application No. 15/601,958, filed on May 22, 2017.
(60) Provisional application No. 62/396,404, filed on Sep. 19, 2016.
(60) Provisional application No. 62/339,341, filed on May 20, 2016.

(51) Int. Cl. F25B 21/02; H01L 35/34; H01L 35/30; H01L 35/32; H01L 23/38

(52) U.S. Cl. CPC F25B 21/02; H01L 35/34; H01L 35/30; F25B 2321/0252; H01L 23/38; F25B 2321/023; H01L 35/32

(57) ABSTRACT

Cooling sub-assemblies with thermoelectric element(s), coupling clamps, hot side and cold side heat exchanger having a direct insertion or removal of cooling modules onto a fixed mounting frame arranged in rows and columns to produce desired and required cooling levels.

### CROSS REFERENCE TO RELATED APPLICATIONS

This application is a continuation-in-part of U.S. Non-Provisional application Ser. No. 15/601,958 filed May 22, 2017, which claims benefit of U.S. Provisional Patent Application No. 62/339,341, filed May 20, 2016, entitled Enhanced Thermoelectric Cooling with Heat Pipes and/or Pyrolytic Graphite Film and U.S. Provisional Patent Application No. 62/396,404, filed Sep. 19, 2016, entitled Construction of a Thin-Flat Heat Pipe Air Conditioner, the disclosures of which are incorporated herein by reference in their entirety.

### BACKGROUND OF THE INVENTION

### a) Field of the Invention

The invention relates to a dual heat pipe thermoelectric cooler using preassembled modules.

### b) Description of the Related Art

Individual heat transfer of cooling modules as known in the art do not produce enough cooling for many industrial applications so that grouping is required. Direct assembly of individual parts would work but is inefficient and costly. Direct vertical insertion into a mounting frame is not an option because the need for sealing and very close spacing of the individual modules. The present invention described herein, uses pre-assembled cooling modules populated onto a single mounting platform (frame) in an inventive form.

### SUMMARY OF THE INVENTION

It is accordingly an object of the invention to provide a method and device for thermoelectric cooling, which overcomes the above-mentioned and other disadvantages of the heretofore-known devices and methods of this general type and which provides for an improvement over the prior art and solves the problem of removing heat from a sealed contained space.

With the foregoing and other objects in view there is provided a thermoelectric cooling system having a mounting plate, a first flat heat pipe connected to the mounting plate and extending through the mounting plate from a first side to a second side of the mounting plate, a second flat heat pipe disposed on the second side and mounted onto the mounting plate, and a thermoelectric module sandwiched between planar sides of the first and second heat pipes on the second side of the mounting plate.

In accordance with another feature of the invention at least one of the first and second heat pipes is an extruded microchannel heat pipe having a plurality of individual channels.

In accordance with an added feature of the invention, the heat pipes contain acetone or 3M™ Fluorinert™ Liquid FC-72.

In accordance with another feature of the invention the heat pipes contain a fluorocarbon or other working fluids.

In accordance with yet another additional feature of the invention the heat pipes contain a working fluid having a boiling point within an operational range of 40 degrees to 200 degrees Fahrenheit.

In accordance with still another added feature of the invention the first and second heat pipes are extruded microchannel heat pipes having a plurality of individual channels.

In accordance with yet still another added feature of the invention the first and second heat pipes each have respective fins disposed along a length thereof.

In accordance with yet still another further feature of the invention the fins have opposing turned up edges.

In accordance with another further feature of the invention, the first and second heat pipes are tilted with respect to an orthogonal of the mounting plate.

With the objects of the invention in view, there is also provided clamp plates sandwiching the first and second heat pipes and the thermoelectric element together.

In accordance with still a further feature of the invention an L-shaped bracket attaches the mounting plate to one of the clamp plates.

In accordance with still another feature of the invention, the mounting plate has a central opening formed therein and a slot extending from an edge of the opening, the slot receiving the first flat heat pipe.

In accordance with yet an additional feature of the invention, there is a seal between the slot and the first flat heat pipe.

In accordance with yet an added feature of the invention, there is a pressure cap disposed on an end of the first flat heat pipe for preventing fluid escape into a sealed enclosure that is to be cooled by the cooling system.

Although the invention is illustrated and described herein as embodied in a dual heat pipe thermoelectric cooler, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1A is a schematic front view of a partial assembly hot side 13 inch by 13 inch mounting frame;

FIG. 1B is a view of a four module 13 inch by 13 inch mounting frame;

FIG. 1C is a view of the slot profile;

FIG. 2 is a sectional side view of the construction of a thermoelectric enclosure cooler using an array of prefabricated thermoelectric cooling modules showing two modules;

FIG. 3 is a comparison chart showing the improved thermal performance of new heat-pipe modules of the present invention with heat dissipation on the Y-axis and temperature change from ambient on the X-axis based on a standard AAC 141 chart from ThermoTEC™ EIC Solutions, Inc., Warinster, Pa.;

FIG. 4 is a view of the new slot detail for fin improvement to enhance interface heat transfer;

FIG. 5A shows various heat pipe construction styles;

FIG. 5B shows a flattened dual round heat pipe style;

FIG. 6A shows a thermoelectric clamp set having two clamp plates;

FIG. 6B shows a side view and a front view of heat pipe configurations mounted on an angle;

FIG. 7A is a perspective view of an assembly of thermoelectric enclosure cooler;

FIG. 7B is a perspective view of the sub assembly of FIG. 7A mounted to an enclosure to be cooled;

FIG. 7C is a perspective view of a partial assembly of the device of FIG. 7A including a mounting frame;

FIG. 8A is a sectional side view of FIG. 7C;

FIG. 8B is a plan view of FIG. 7C;

FIG. 8C is a side view of FIG. 7C;

FIG. 9 is a section view along section line H-H of FIGS. 8B and 8C;

FIG. 10A is a view of another mounting frame;

FIG. 10B is an enlarged view of detail “E” in FIG. 10A;

FIG. 11A is a side view of a cooling module of FIG. 7C;

FIG. 11B is an enlarged view of detail “11B” in FIG. 11A;

FIG. 11C is an enlarged side view of a portion of the cooling module of FIG. 7C;

FIG. 11D is an enlarged view of detail “11D” in FIG. 11C; and

FIG. 11E is an enlarged view of detail “E” in FIG. 11A.

### DESCRIPTION OF THE PREFERRED EMBODIMENTS

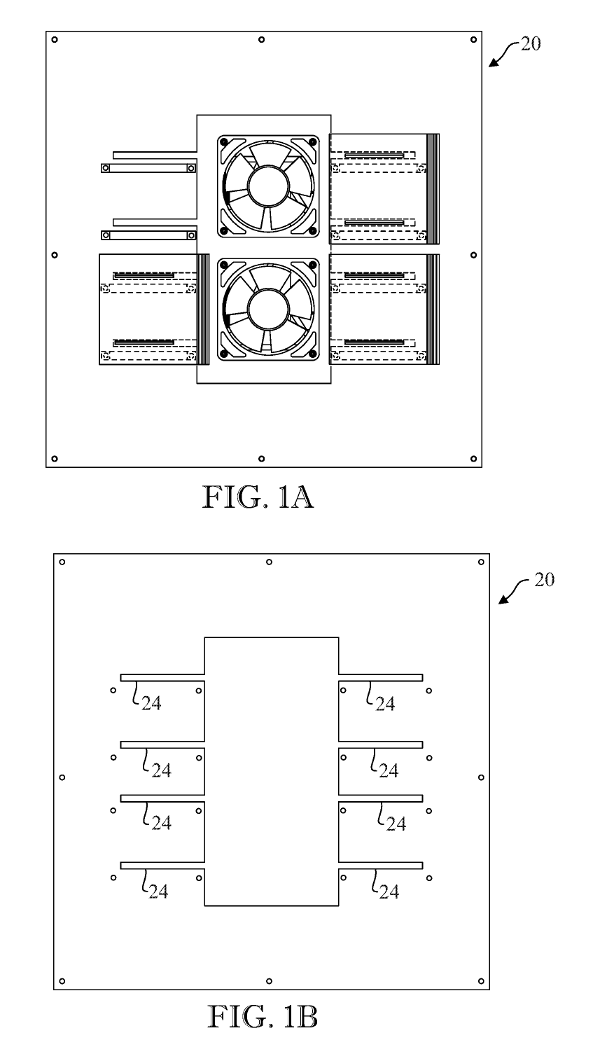

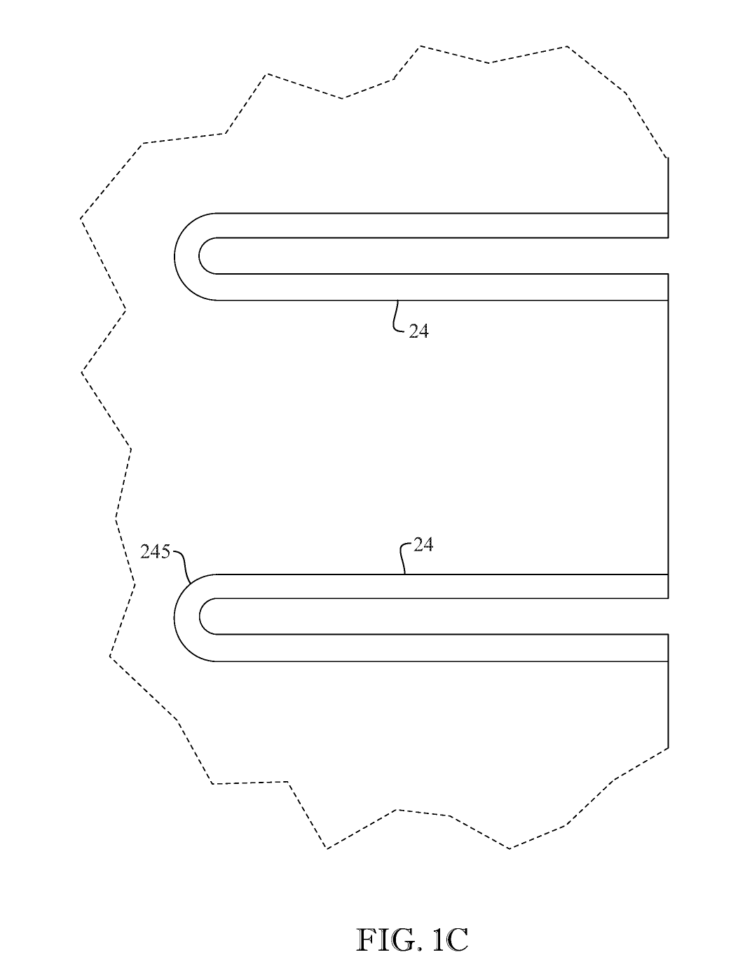

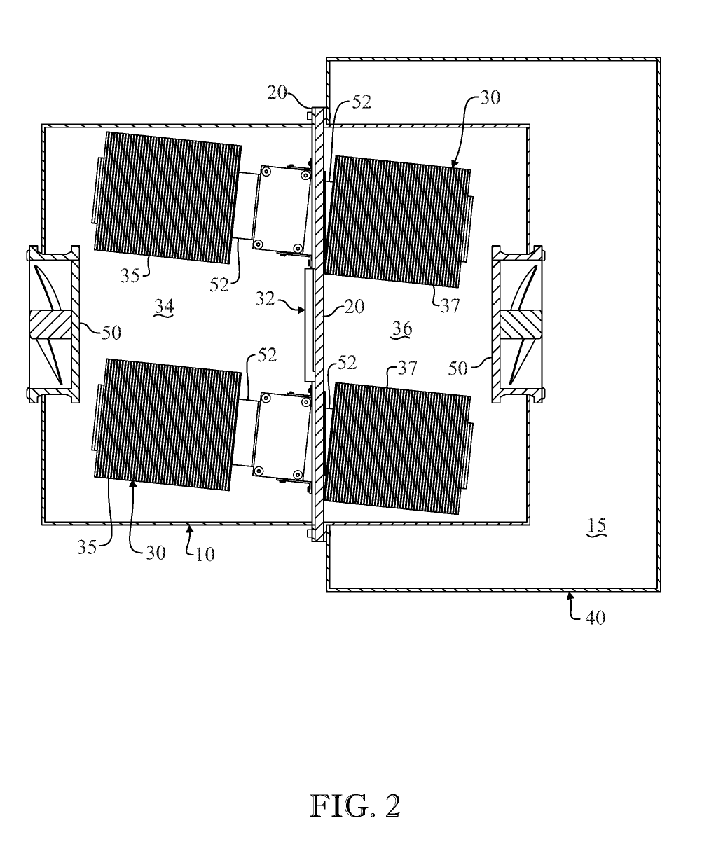

Referring now to the figures of the drawing in detail and first, particularly to FIGS. 1A, 1B, 1C and 2.

The present invention discloses a dual heat pipe thermoelectric cooler using individual cooling sub-assemblies with thermoelectric element(s), coupling clamps, hot side and cold side heat exchanger(s) (referred to as thermoelectric cooling modules or module). The present invention pertains to direct insertion or removal of cooling modules onto a fixed mounting frame 20, a standard size is 13 inches by 13 inches. This mounting frame 20 is arranged to support cooling modules 30 in rows and columns to produce desired and required cooling levels. The thermoelectric cooling modules 30 of the present invention have been manufactured tested and produce 80 watts (273 BTU) or more of cooling.

The mounting frame 20 shown in FIG. 1A shows a prototype design having four (4) cooling modules 30 on an industry standard 13×13 inch frame with space for up to six (6) modules. The frame mounting 20 as shown in FIG. 1B has a large opening 22 in the center of the frame 20 that provides space for an electronic AC to DC (alternating current to direct current) converter or power supply 32 and provides a sealed opening to load or remove modules (for service). Individual thermoelectric cooling modules 30 can be lowered into the opening 22 and inserted into slots 24 (see FIG. 1C) having rubber seals 24s to assure leak free operation.

FIG. 2 shows the construction of a thermoelectric enclosure cooler assembly 10 using an array of prefabricated thermoelectric cooling modules 30. FIG. 2 is a side view of the sealed enclosure to be cooled 40, shown with two thermoelectric cooling modules 30, including part locations and air flow patterns. The enclosure to be cooled 40 includes one or more heat generating components 15 such as electronic circuitry. The assembly 10 has both the waste or hot side 34 of the assembly 10 and the cold side 36 which is totally separate and isolated by the base plate or mounting frame 20 and supplemental insulation (not shown) at the power supply 32 and around the clamping sections. In use, the entire cooler assembly 10 is mounted onto the outside of the sealed enclosure 40 to be cooled through a sealed gasket using mechanical fasteners. There are two thermoelectric modules 30 visible but the device has four (4) as seen from FIG. 1A. Other configurations can carry many other modules to produce desired cooling levels. The cooler assembly 10 outer portion is external of the enclosure 40 and includes the waste heat elements 35 of each of the thermoelectric modules 30. An inner portion of the cooler assembly 10 is disposed inside the enclosure 40 and transfers air which is cooled by respective cooling elements of each of the thermoelectric cooling modules 30 and circulates air (air flow) AF, using fans 50 into the sealed enclosure 40 and back returning through vents V. The thermoelectric cooling modules 30 have heat pipes 52, which pass through slots 24 in the mounting frame 20. The slots 24 are provided with seals 24s that seal the periphery of the heat pipes 52. As seen in FIG. 1C, the slots 24 accommodate the seals 24s (only a portion of which is schematically shown in FIG. 1C). The ac to dc converter power supply 32 uses mains power and generates direct current to activate the thermoelectric modules and fans. Heat produced by the power supply 32 is designed to be expelled to the waste side 34 along with the extracted heat, to maintain cooler efficiency.

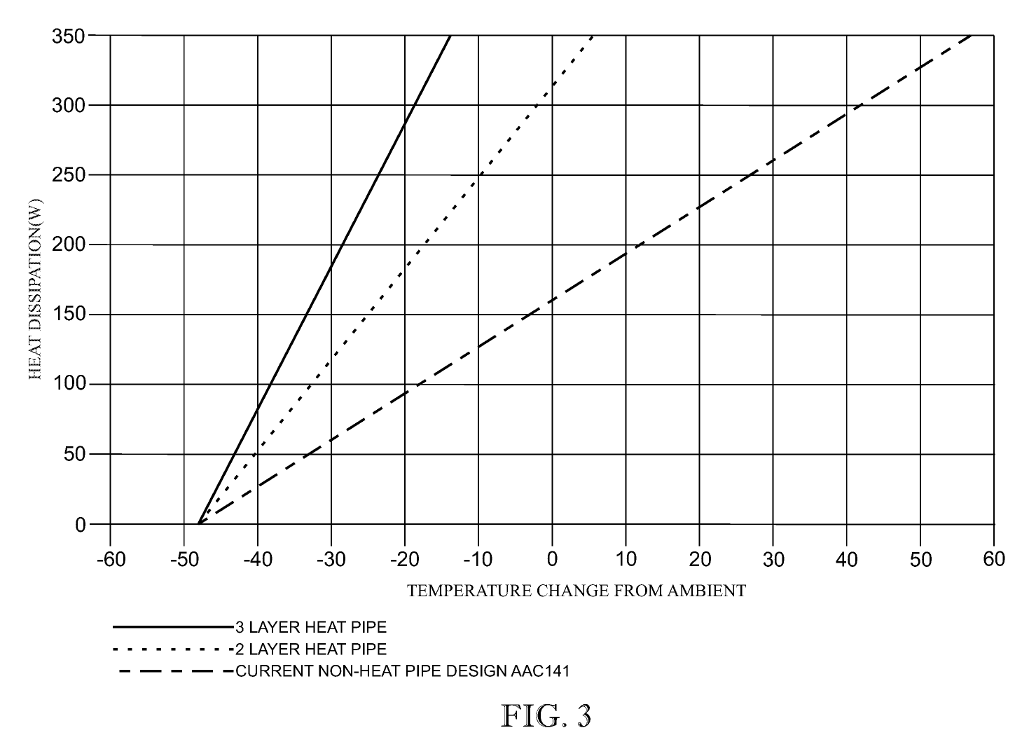

FIG. 3 is a chart that shows projected performance of the new thermoelectric cooler module 30 compared to an existing industrial product manufactured by EIC Solutions, Inc., Warminster, Pa., USA, Model No. AAC-141 having 4 cooling modules. As tested the present invention provides two (2) times improvement and with 6 modules provides three (3) times cooling over the referenced commercial product Model No. AAC-141 within the same 13×13 inch mounting plate format.

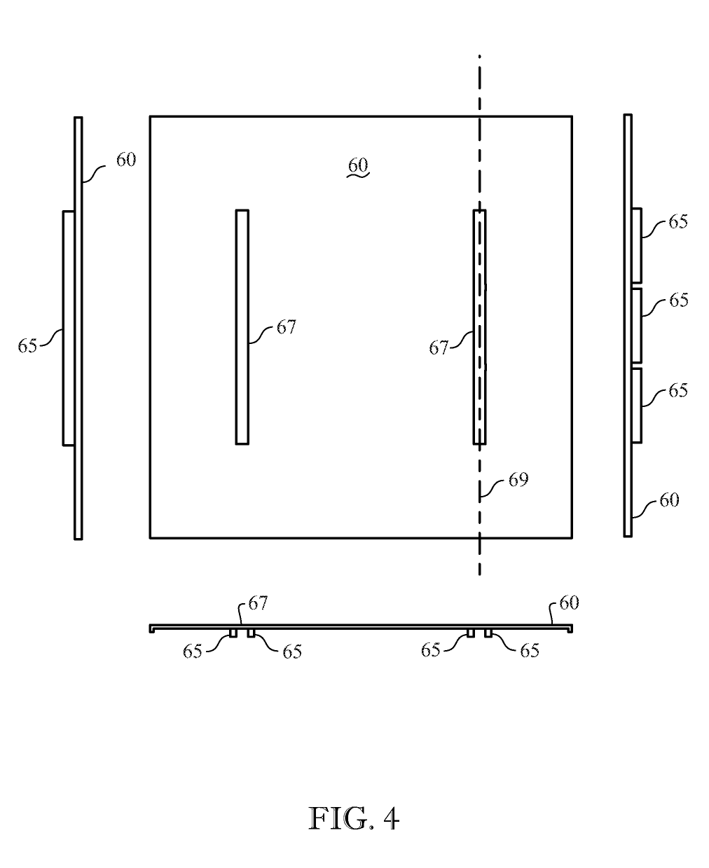

It has been found that the fins 60 of the present invention as shown in FIG. 4 include manufacturing imperfections and applicant found that small imperfections along the long slot shear line 69 flanges 65 tends to separate the entire fin slot 67 from the heat exchanger heat pipe 52 (not shown in this FIG. 4). The present invention divides the long shear line into multiple smaller segments of the flanges 65 and thereby promotes substantially better thermal contact since an imperfection only affects a single section.

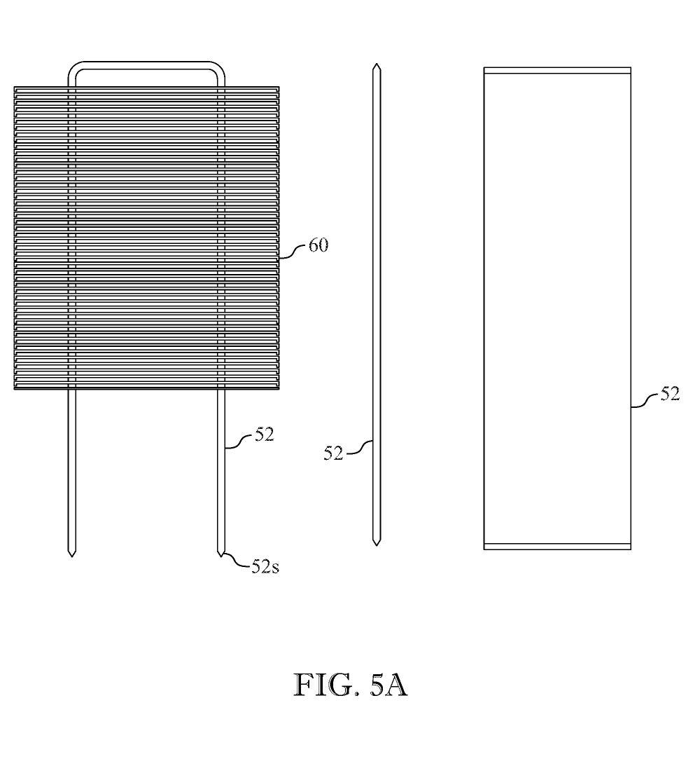

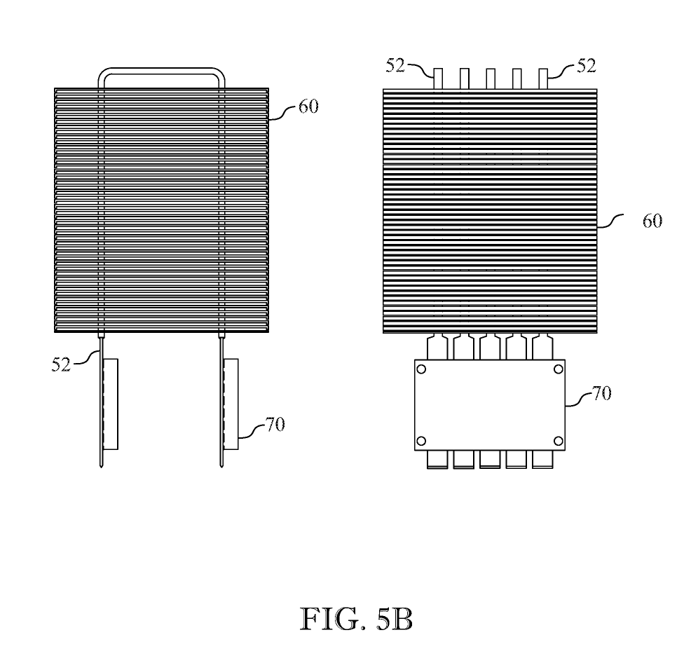

FIGS. 5A and 5B show several alternate configurations for heat pipes 52. FIG. 5A shows both an extruded heat pipe 52 using straight and U-shape elements for use with a dual path thermoelectric element 75, using a U-shape heat pipe 52 that will reduce manufacturing costs with fewer components. The heat pipes 52 have a crimpled seal 52s. FIG. 5B shows a design using a round but flattened U-shaped pipe 52 using water as the working fluid. This configuration can only be used on the heat exchanger on the hot or waste side 34 of the cooling unit. The advantage of this configuration is use of water within the heat pipes is not position sensitive, and works irrespective of the angle.

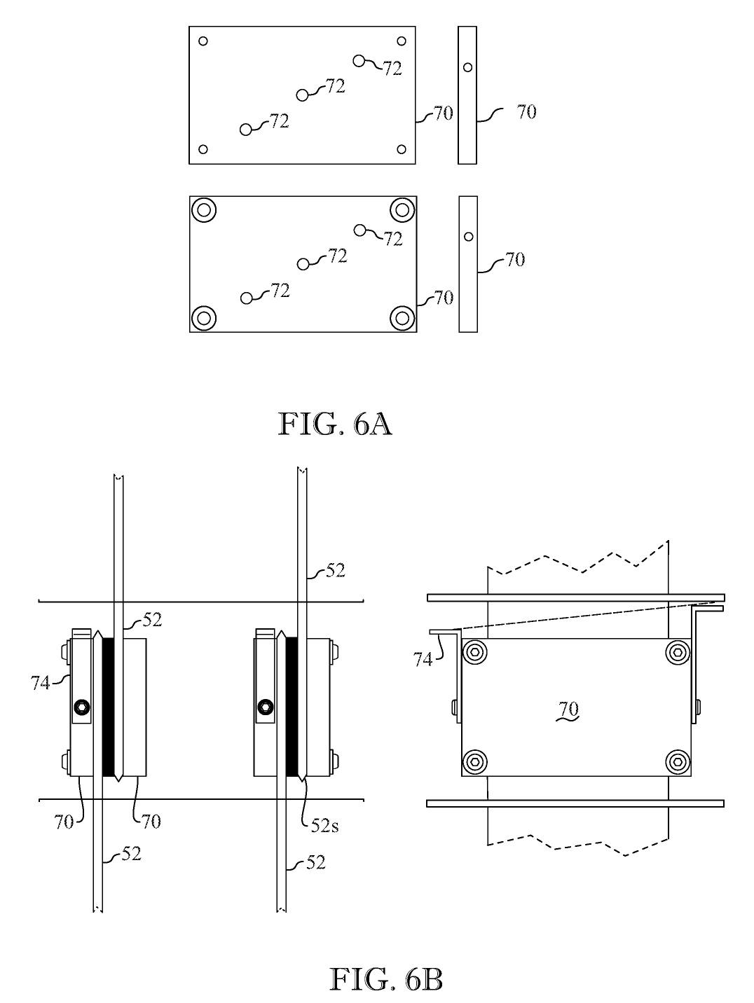

FIG. 6A shows a thermoelectric clamp set 70 with the development of thermal access ports 72 to allow thermocouples or other temperature measuring devices to monitor cooling performance and/or control signals for safety or control purposes, i.e. overheating shutoff signals, calibration or in process testing among others. The ports 72 allow access to the inner portions so that accurate measurements are possible. Thermal samples at locations on the outside will not react as quickly or provide the required critical positional thermal feedback.

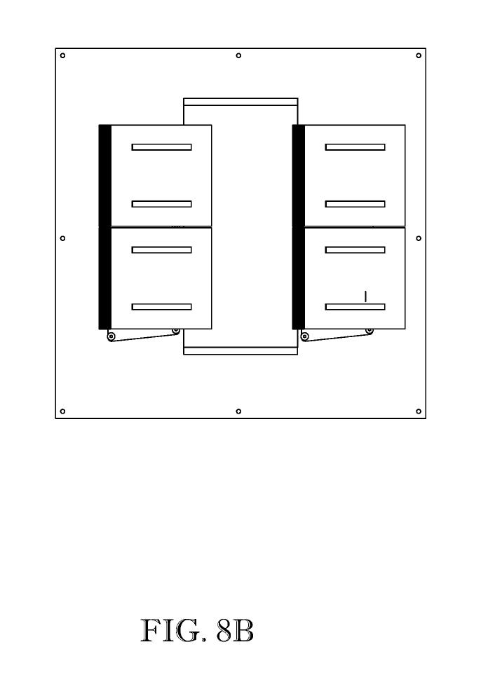

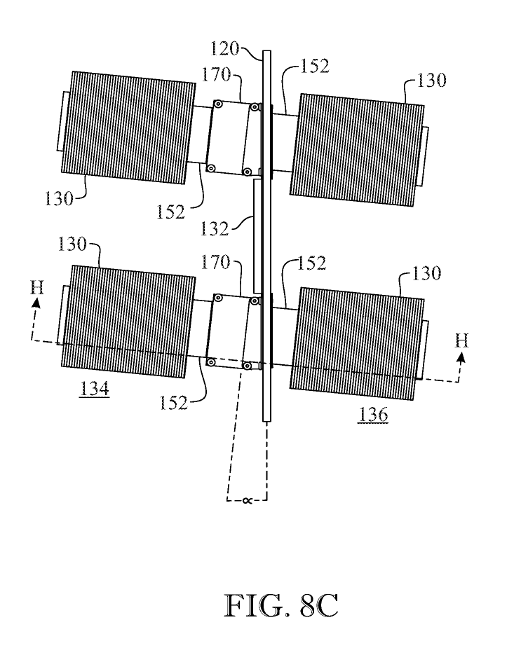

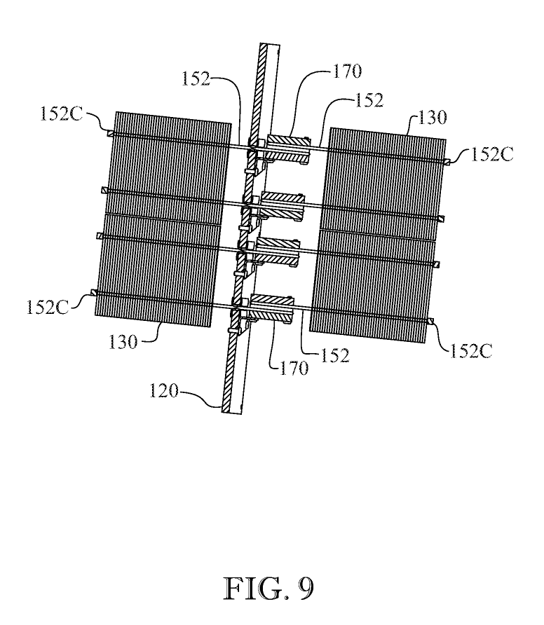

Applicant has found, that as shown in FIG. 6B, some of the heat pipe configurations perform best when mounted on an angle above horizontal. It has been found experimentally that the heat pipe performs best at an angle of approximately six (6) degrees above horizontal, as shown by a in FIGS. 2 and 8C. FIG. 6B shows a tilt bracket 74 to achieve this angle. The bracket 74 is made from a thin gage stainless steel that has very low thermal conductivity. Cross sections are kept long and is constructed and mounted in a way to isolate heat migration from the waste side 35 of the thermoelectric interface to the mounting plate 20. This improvement has shown to reduce parasitic losses.

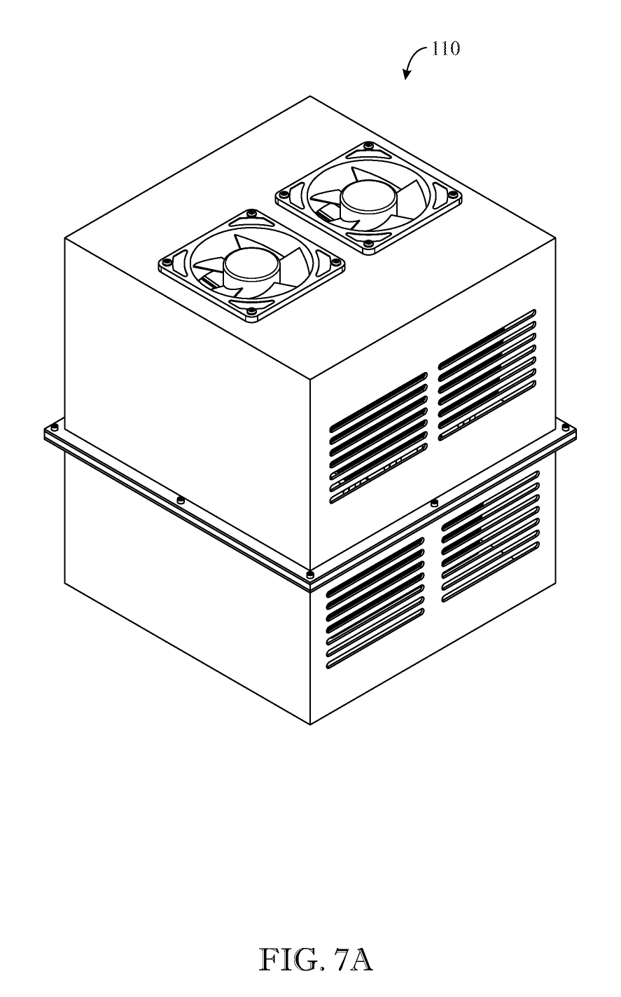

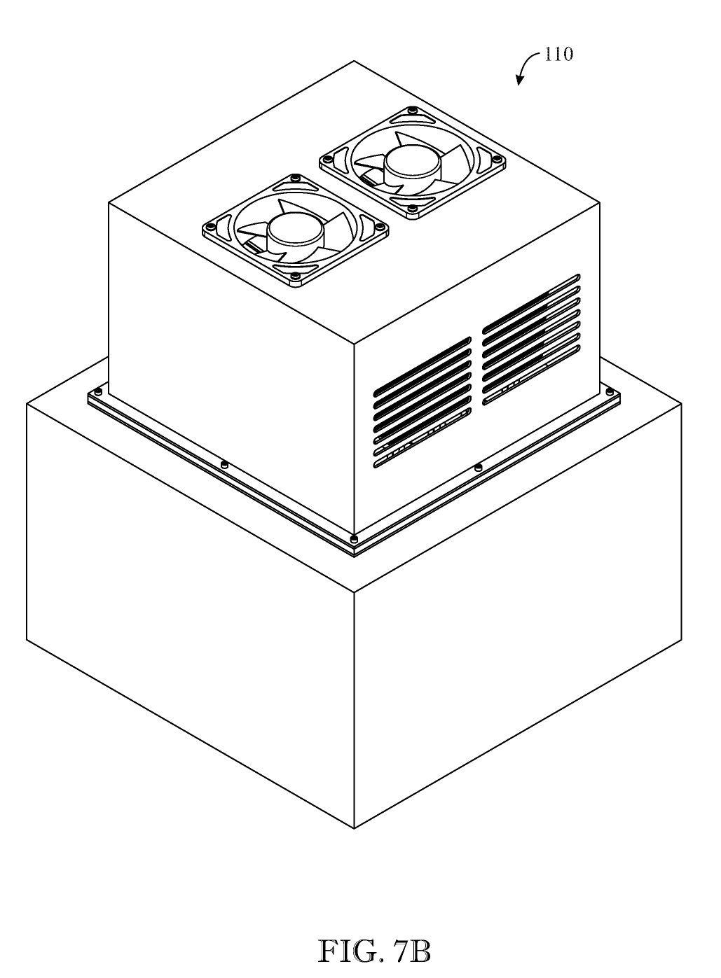

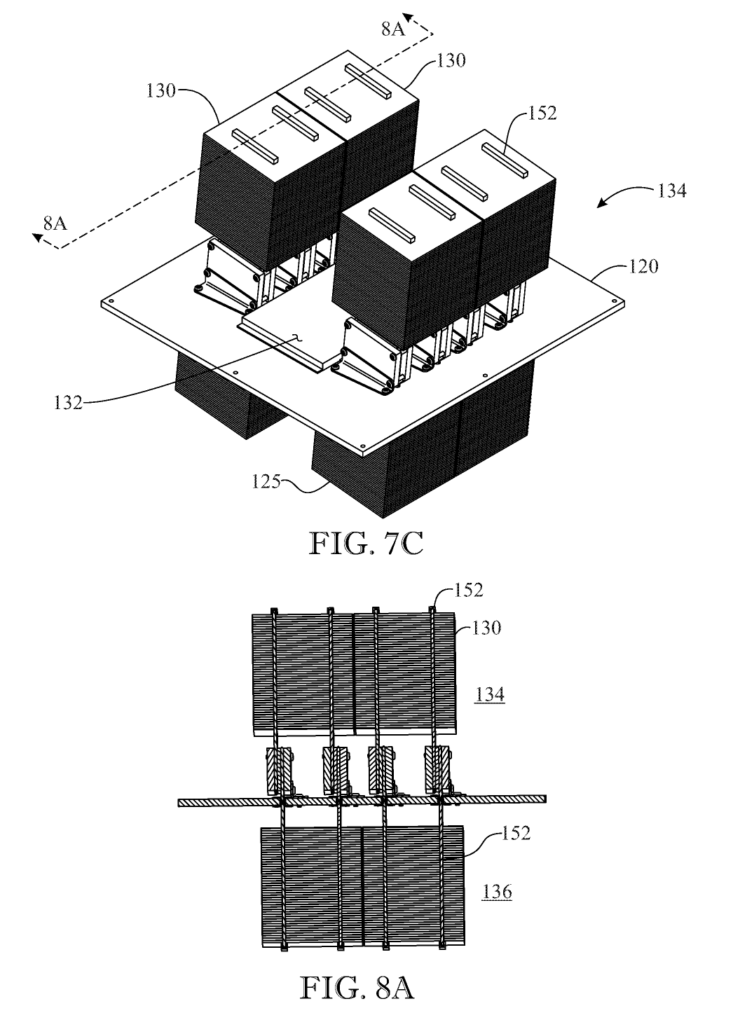

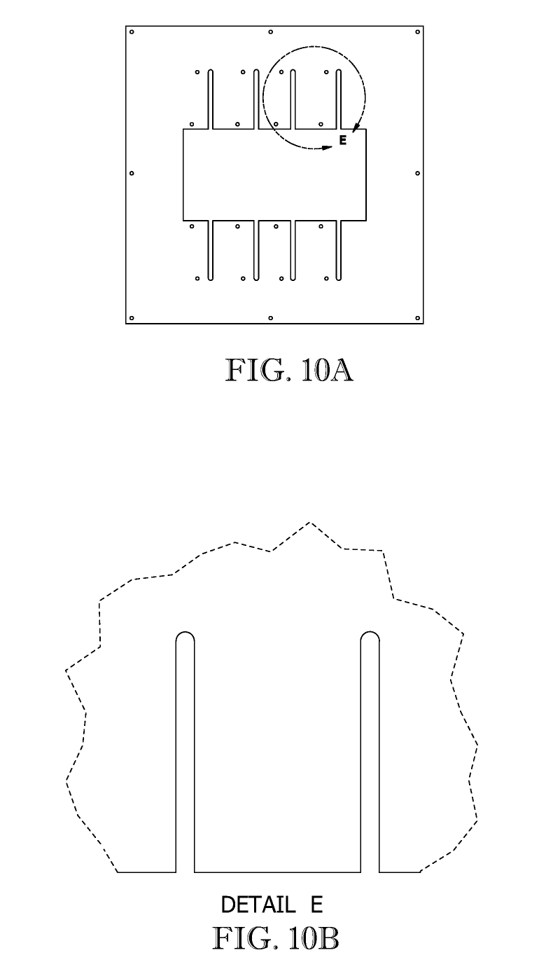

FIGS. 7A-7C show another embodiment of a cooler assembly 110 including heat pipes 152. The heat pipes 152 contain a working fluid having a boiling point within an operational range of 40 degrees to 200 degrees Fahrenheit. A working fluid can a fluorocarbon or an acetone such as 3M™, Fluorinert™ Liquid FC-72, trademarks of 3M Company, 2501 Hudson Road St. Paul MINNESOTA 55144, FIG. 7C shows the hot side 134 of the assembly 110. The fixed frame 120 is provided with the power supply 132 at the cutout 122 (FIG. 10A). The cutout 122 has slots 124 on longitudinal sides of the cutout 122. This construction allows the cooling modules 130 to be easily assembled to the frame 120. The heat pipes 152 of the cold side 136 are moved into the cutout 122 and slid into the slots 124 along the longitudinal direction of the slots 124. The mounting frame 120 is also provided with holes 125 around the periphery for holding the assembly 110 together and fixing to the enclosure 140. Ends of the heat pipes 152 in the cold side 136 may be provided with pressure caps 152c that serve to ensure that fluid does not escape from the heat pipes 152 into the enclosure 140. The frame 120 is also provided with openings 126 for affixing brackets 174 of the cooling modules 130, which hold the cooling modules in place on the frame 120, as will be described in further detail hereinafter.

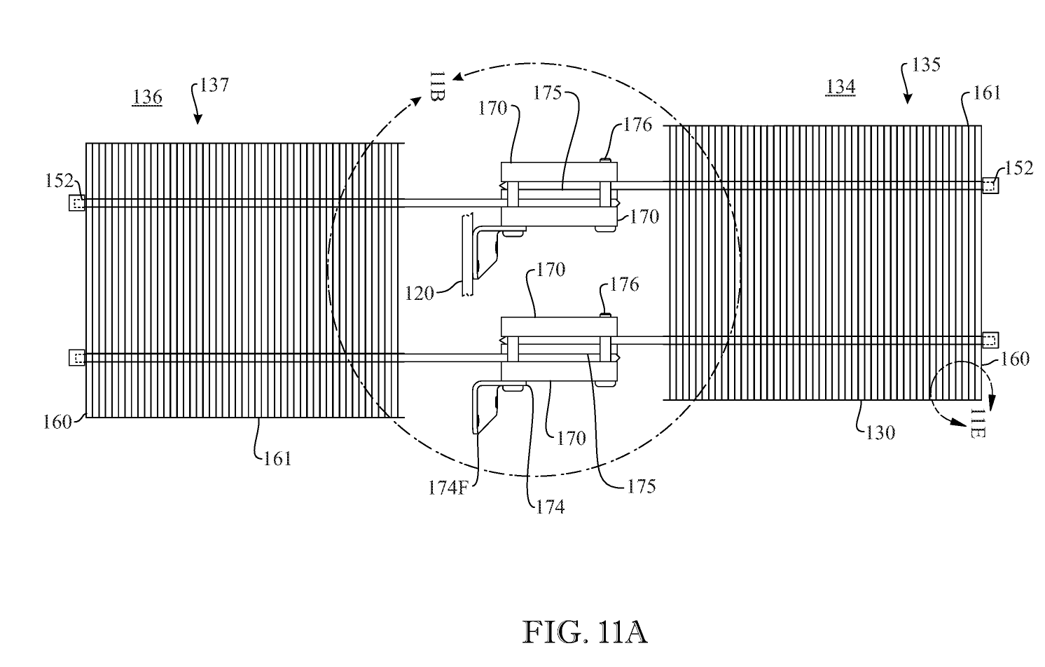

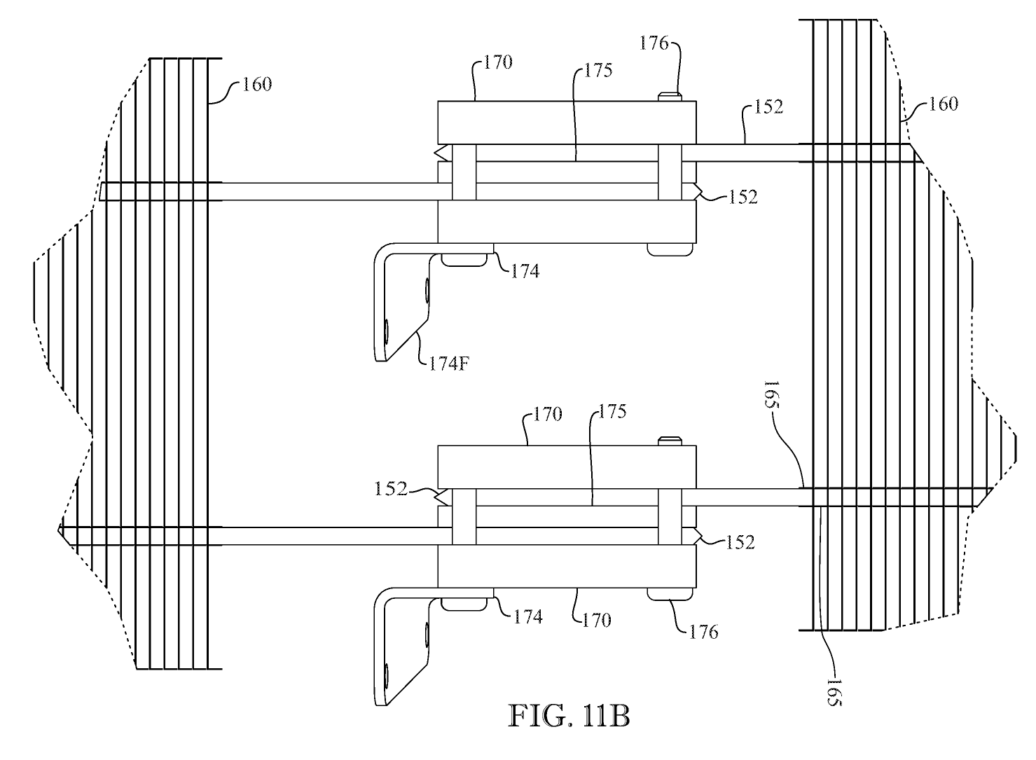

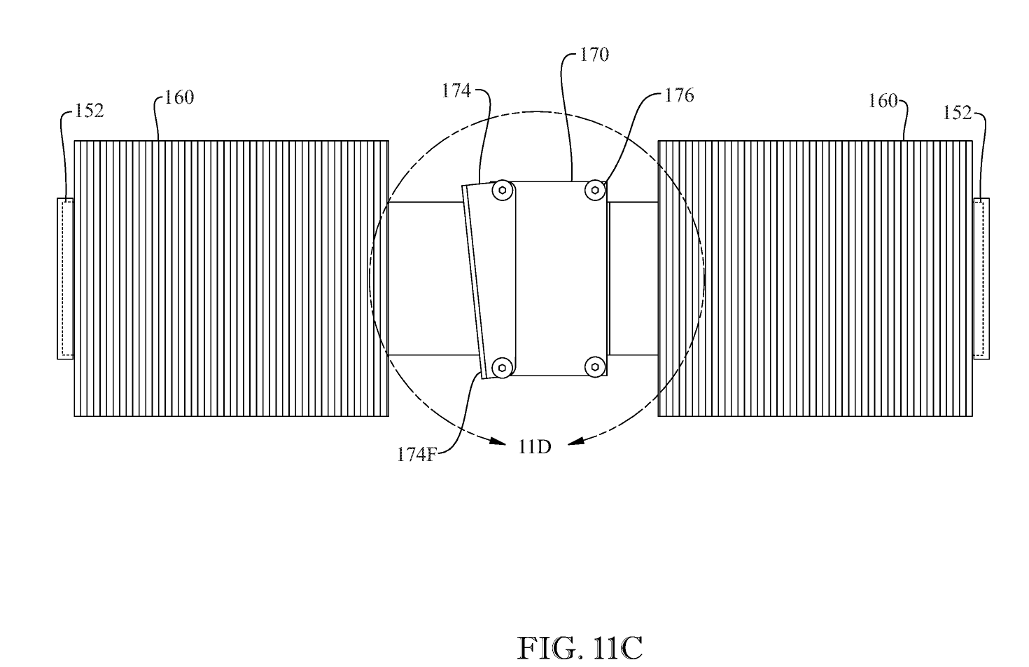

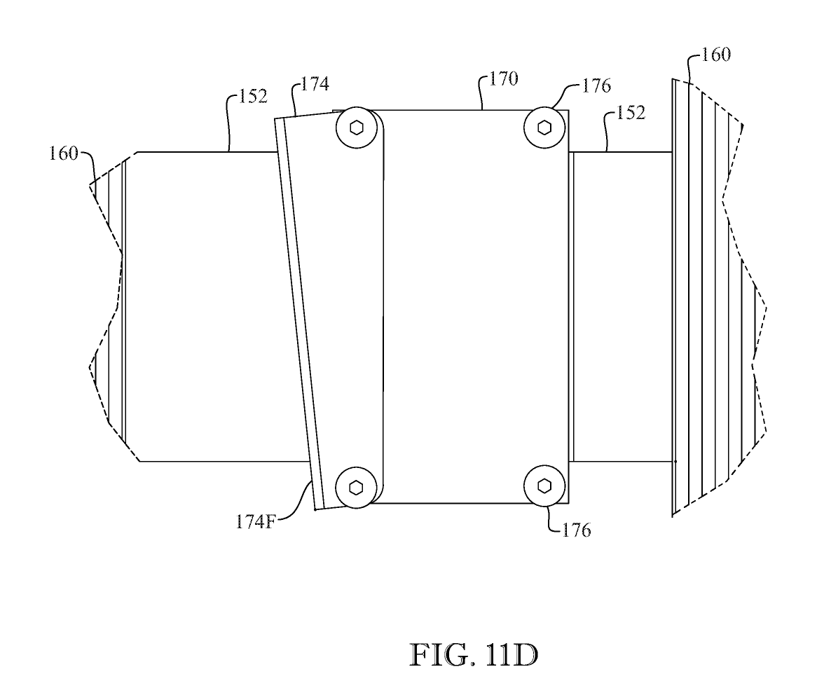

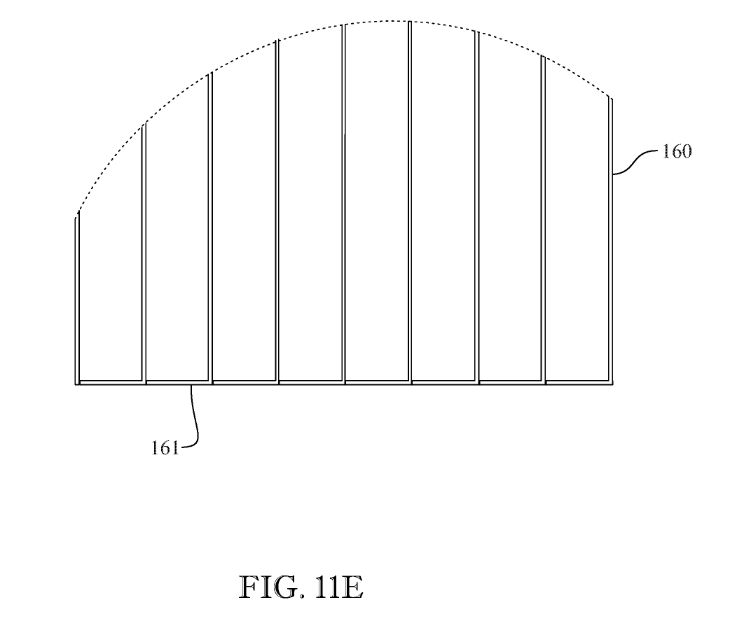

FIGS. 11A-11E show the cooling modules 130, which each include two spaced apart heat pipes 152 on the cold side 136 that extend parallel to one another through the mounting frame 120. The heat pipes may be AMEC Thermosol Ultra flat Heat pipes (also known as Coolpipe) MHP Series (AMEC Thermasol is a division of Marcom Electronic Components (UK) Ltd. AMEC Thermasol, Marcom House, 1-2 Steam Mill Lane, Great Yarmouth, Norfolk, NR31 0HP, United Kingdom). As is shown in FIG. 11A, the heat pipes 152 on the cold side 136 are provided with a plurality of fins 160 that are stacked along the length of the heat pipes 152. The fins 160 are provided with parallel slots 67 as is shown in FIG. 4. The ends of the fins 160 include turned up edges 161 that are parallel to the heat pipes 152 and which help increase the heat transfer of the fins 160 and assist in setting a spacing between adjacent fins 160. The hot side 134 has the same construction as the cold side 136 with respect to the fins 160 and the heat pipes 152. However, the heat pipes 152 do not extend through the frame 120. The heat pipes 152 of the hot side 134 and the cold side 136 are sandwiched together. Particularly, the heat pipes 152 have a thermoelectric element 175 disposed therebetween, which is in contact with the planar sides of the heat pipes 152. The heat pipes 152 and the thermoelectric element 175 are sandwiched between clamp plates 170 held together by fasteners 176 at the corners of the clamp plates 170. Also provided on one of the clamp plates is the bracket 174, which has an L-shaped cross-section. As is seen in FIGS. 11B and 11D the holes in the bracket 174, which accept the fasteners 176 are spaced differently from a mounting flange 174f of the bracket 174 so as to provide a tilt of the heat pipes 152, when the bracket 174 is fastened to the frame 120 by the holes 126. This tilt is shown in FIG. 8C. The tilt angle α is preferably 6° as noted above with respect to FIGS. 2 and 8C. The interfaces between the heat pipes 152, fins 160, and thermoelectric element 175 can all be provided with a thermal conductive adhesive there between (manufactured by Casco within the Sika Group, Baar Switzerland) so as to provide the best heat transfer in the cooling modules 130. Also, as shown in FIG. 11B, flanges 165 in accordance with flanges 65 promote substantially better thermal contact.

The operation of the device is such that the medium in the cold side 136 heat pipes 152 flows to the ends of the respective heat pipes 152 from the thermoelectric element 175. The fans 150 draw air over the fins 160 of the cold air element 137 and issues cool air into the enclosure 140 for cooling the component contained within the enclosure 140. This results in the air being heated by the components provided inside the enclosure 140 and heats the medium in the pipes 152. As the medium is heated it becomes vapor and travels to the thermoelectric element 175 where the medium is again cooled and returned to a liquid state, which allows the medium to flow back down the heat pipes 152 due to the effects of gravity and the 6° tilt angle α so that cold air is provided within the enclosure 140.

The heat pipes 152 on the hot side 134 are heated at the thermoelectric elements 175 so that the medium vaporizes and travels to the ends of the respective heat pipes 152. The medium is cooled along the length of the heat pipes 152 on the hot side 134, with the help of the fins 160 of the waste heat elements 135, until the medium returns to a liquid state and flows back toward the thermoelectric element 175 due to the tilt angle, where the medium again heats to complete the continuous cycle. The fans 150 pull air over the fins 160 of the waste heat elements 135 and issue hot air to cool the medium as the medium travels along the length of the heat pipes 152.

The inventor has discovered that the invention results in a temperature difference from the thermoelectric element 175 to the ends of the fins 160 of 1° C. versus 8° C. for cooling device according to the prior art. Therefore, the present invention greatly improves the efficiency of heat transfer. The above results in at least a threefold improvement in heat removal and greatly reduces the footprint required for the heat exchanger. This in turn allows more room for additional heat-generating components in the enclosure 40/140.

I claim:

1. A thermoelectric cooling system comprising:
a mounting plate:
a first flat heat pipe connected to said mounting plate and extending through said mounting plate from a first side to a second side of said mounting plate;
a second flat heat pipe disposed on said second side and mounted onto said mounting plate;
a thermoelectric module sandwiched between planar sides of said first and second heat pipes on said second side of said mounting plate.

2. The thermoelectric cooling system set according to claim 1, wherein at least one of said first and second heat pipes is an extruded microchannel heat pipe having a plurality of individual channels.

3. The thermoelectric cooling system set forth in claim 2, wherein said heat pipes contain acetone or 3M™ Fluorinert™ Liquid FC-72.

4. The thermoelectric cooling system set forth in claim 2, wherein said heat pipes contain a fluorocarbon or other working fluids.

5. The thermoelectric cooling system set forth in claim 2, wherein said heat pipes contain a working fluid having a boiling point within an operational range of 40 degrees to 200 degrees Fahrenheit.

6. The thermoelectric cooling system set according to claim 1, wherein said first and second heat pipes are extruded microchannel heat pipe having a plurality of individual channels.

7. The thermoelectric cooling system set according to claim 1, wherein said first and second heat pipes each have respective fins disposed along a length thereof.

8. The thermoelectric cooling system according to claim 6, wherein said fins have opposing turned up edges.

9. The thermoelectric cooling system according to claim 1, wherein said first and second heat pipes are tilted with respect an orthogonal of said mounting plate.

10. The thermoelectric cooling system according to claim 9, further comprising clamp plates sandwiching said first and second heat pipes and said thermoelectric element together.

11. The thermoelectric cooling system according to claim 10, further comprising an L-shaped bracket attaching said mounting plate to one of said clamp plates.

12. The thermoelectric cooling system according to claim 1, wherein said mounting plate has a central opening formed therein and a slot extending from an edge of said opening, said slot receiving said first flat heat pipe.

13. The thermoelectric cooling system according to claim 12, further comprising a seal between said slot and said first flat heat pipe.

14. The thermoelectric cooling system according to claim 1, further comprising a pressure cap disposed on an end of said first flat heat pipe for preventing fluid escape into a sealed enclosure that is to be cooled by the cooling system.
